(19) United States
(12) Patent Application Publication
(10) Pub. No.: US 2022/0190133 A1
(43) Pub. Date: Jun. 16, 2022

(54) SEMICONDUCTOR STRUCTURE

(71) Applicant: NANYA TECHNOLOGY CORPORATION, New Taipei City (TW)

(72) Inventor: Wei-Chih WANG, Taoyuan City (TW)

(21) Appl. No.: 17/118,560

(22) Filed: Dec. 10, 2020

(51) Int. Cl. H01L 29/423; H01L 29/78

(52) U.S. Cl. CPC H01L 29/42376; H01L 29/7833

(57) ABSTRACT

A semiconductor structure includes a substrate and a gate structure. The substrate includes a source region and a drain region. The source region is located in a first area of the substrate. The drain region is located in a second area of the substrate. The gate structure includes a first gate region and a second gate region. The first gate region is disposed above the first area of the substrate or disposed above the second area of the substrate. The second gate region is disposed above a third area of the substrate. A second height of the second gate region is higher than a first height of the first gate region.

### BACKGROUND

### Field of Invention

The present disclosure relates to a semiconductor structure. More particularly, the present disclosure relates to a semiconductor structure having different gate heights.

### Description of Related Art

As the size of the electronic device becomes smaller and smaller, RC (resistor-capacitor) delay is a key factor to improve integrated circuit performance. Integrated circuits with high resistance and capacitance would induce delay time and circuit fails.

For the foregoing reason, there is a need to provide some other suitable semiconductor structure used in the integrated circuits to solve the problems of the prior art.

### SUMMARY

One aspect of the present disclosure provides semiconductor structure. The semiconductor structure includes a substrate and a gate structure. The substrate includes a source region and a drain region. The source region is located in a first area of the substrate. The drain region is located in a second area of the substrate. The gate structure includes a first gate region and a second gate region. The first gate region is disposed above the first area of the substrate or disposed above the second area of the substrate. The second gate region is disposed above a third area of the substrate. A second height of the second gate region is higher than a first height of the first gate region.

These and other aspects of the present disclosure will become apparent from the following description of the preferred embodiment taken in conjunction with the following drawings, although variations and modifications therein may be effected without departing from the spirit and scope of the novel concepts of the disclosure.

It is to be understood that both the foregoing general description and the following detailed description are by examples, and are intended to provide further explanation of the present disclosure as claimed.

### BRIEF DESCRIPTION OF THE DRAWINGS

The present disclosure can be more fully understood by reading the following detailed description of the embodiment, with reference made to the accompanying drawings as follows:

FIG. 1 schematically shows a schematic diagram of a semiconductor structure according to one embodiment of the present disclosure;

FIG. 2 schematically shows a schematic diagram of a semiconductor structure according to one embodiment of the present disclosure; and

FIG. 3 schematically shows a schematic diagram of a semiconductor structure according to one embodiment of the present disclosure.

### DETAILED DESCRIPTION

Reference will now be made in detail to the present embodiments of the present disclosure, examples of which are illustrated in the accompanying drawings. Wherever possible, the same reference numbers are used in the drawings and the description to refer to the same or like parts.

The terminology used herein is for the purpose of describing particular example embodiments only and is not intended to be limiting of the present disclosure. As used herein, the singular forms “a,” “an” and “the” are intended to include the plural forms as well, unless the context clearly indicates otherwise.

Furthermore, it should be understood that the terms, “comprising”, “including”, “having”, “containing”, “involving” and the like, used herein are open-ended, that is, including but not limited to.

The terms used in this specification and claims, unless otherwise stated, generally have their ordinary meanings in the art, within the context of the disclosure, and in the specific context where each term is used. Certain terms that are used to describe the disclosure are discussed below, or elsewhere in the specification, to provide additional guidance to the practitioner skilled in the art regarding the description of the disclosure.

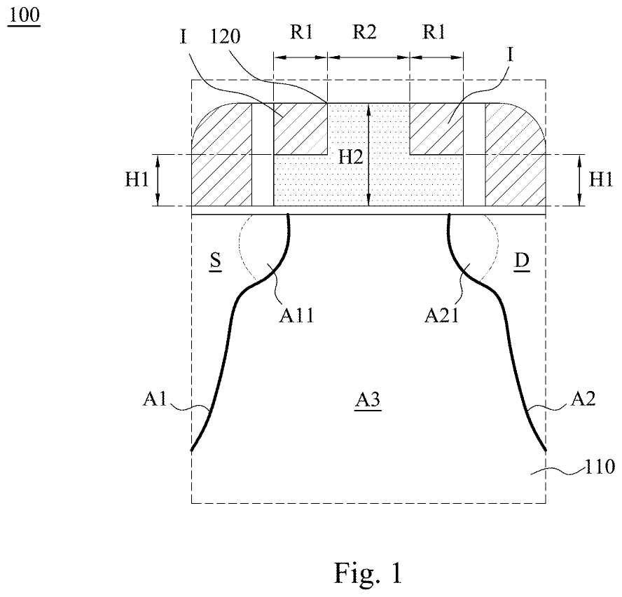

FIG. 1 schematically shows a schematic diagram of a semiconductor structure according to one embodiment of the present disclosure. A description is provided with reference to FIG. 1. The semiconductor structure 100 includes CMOS (Complementary Metal-Oxide-Semiconductor).

In some embodiments, the semiconductor structure 100 includes a substrate 110 and a gate structure 120. The substrate 110 includes a source region S and a drain region D. The source region S is located in a first area A1 of the substrate 110. The drain region D is located in a second area A2 of the substrate 110. The gate structure 120 includes a first gate region R1 and a second gate region R2. The first gate region R1 is disposed above the first area A1 of the substrate 100 or disposed above the second area A2 of the substrate 110. The second gate region R2 is disposed above a third area A3 of the substrate 110. A second height H2 of the second gate region R2 is higher than a first height H1 of the first gate region R1.

In some embodiments, the first area A1 and the second area A2 are located at two opposite sides of the substrate 110 respectively. For example, the first area A1 are located at the left side of the substrate 110, and the second area A2 is located at the right side of the substrate 110.

In some embodiments, the source region S further includes a first lightly doped drain (LDD) region A11, and the drain region D further includes a second lightly doped drain (LDD) region A21. In some embodiments, the doping concentration of the first lightly doped drain region A11 and the second lightly doped drain region A21 affect the resistance of the semiconductor structure 100. The resistance of the semiconductor structure 100 is proportional to the doping concentration of the first lightly doped drain region A11 and the second lightly doped drain region A21. The doping concentration of lightly doped drain region is designed according to actual demands.

In some embodiments, the first gate region R1 includes two first gate regions. One of the two first gate regions R1 is disposed above the first area A1 of the substrate 110, and the other one of the two first gate regions R1 is disposed above the second area A2 of the substrate 110. For example, the first gate region R1 located at the left side is disposed above the first area A1 of the substrate 110, and the first gate region R1 located at the right side is disposed above the second area A2 of the substrate 110.

In some embodiments, the two first gate regions R1 are coupled to the drain region D and the source region S respectively. For example, the first gate region R1 disposed at the right side is coupled to the drain region D, and the first gate region R1 disposed at the left side is coupled to the source region S.

In some embodiments, the third area A3 is between the first area A1 and the second area A2, and the third area A3 is in contact with the first area A1 and the second area A2. In some embodiments, the third area A3 is located at a center of the substrate 110.

In some embodiments, a proportion of the first height H1 of the first gate region R1 to the second height H2 of the second gate region R2 is about 50%. It is noted that the parasitic capacitance between the first lightly doped drain (LDD) region A11 and the first gate region R1 relates to the height of gate structure. The parasitic capacitance between the second lightly doped drain (LDD) region A21 and the first gate region R1 also relates to the gate height of gate structure.

It is noted that parasitic capacitance is proportional to the overlapped area of the gate structure and the drain region, or the overlapped area of the gate structure and the source region. In other word, the lower the gate height gets, the lower the parasitic capacitance becomes.

In some embodiments, the second height H2 of the second gate region R2 is about 30 nm. In some embodiments, the first height H1 of the first gate region R1 is about 15 nm.

In some embodiments, the interspace I located above each of the two first regions R1 is filled with oxide or nitride or low-κ dielectric materials.

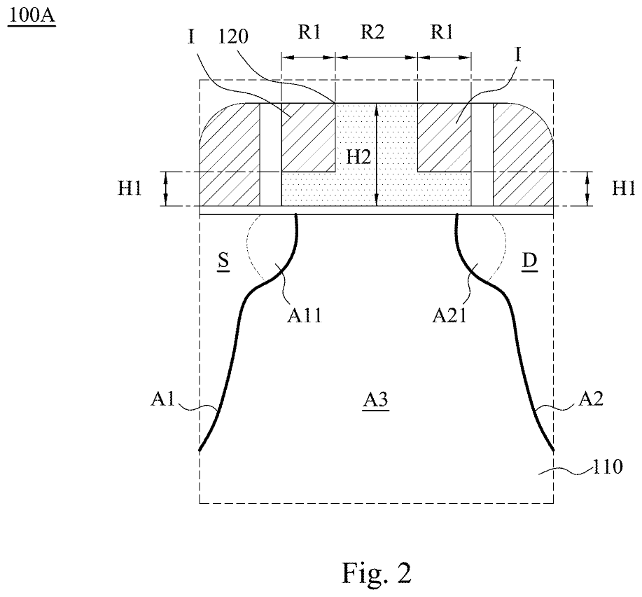

FIG. 2 schematically shows a schematic diagram of a semiconductor structure according to one embodiment of the present disclosure. Compared to the semiconductor structure 100 in FIG. 1, the semiconductor structure 100A shown in FIG. 2 only changes the gate height of the first gate region R1.

In some embodiments, please refer to FIG. 2, a proportion of the first height H1 of the first gate region R1 to the second height H2 of the second gate region R2 is about 35%.

In some embodiments, the second height H2 of the second gate region R2 is about 30 nm, and the first height H1 of the first gate region R1 is about 10 nm. In this embodiment, a proportion of the first height H1 of the first gate region R1 to the second height H2 of the second gate region R2 is 33.33%.

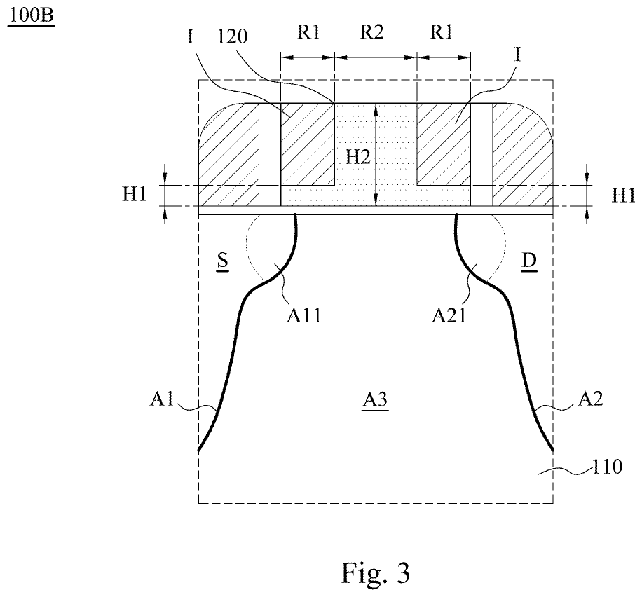

FIG. 3 schematically shows a schematic diagram of a semiconductor structure according to one embodiment of the present disclosure. Compared to the semiconductor structure 100 in FIG. 1, the semiconductor structure 1008 only change the gate height of the first gate region R1.

In some embodiments, please refer to FIG. 3, a proportion of the first height H1 of the first gate region R1 to the second height H2 of the second gate region R2 is about 20%.

In some embodiments, the second height H2 of the second gate region R2 is about 30 nm, and the first height H1 of the first gate region R1 is about 5 nm. In this embodiment, a proportion of the first height H1 of the first gate region R1 to the second height H2 of the second gate region R2 is 16.67%.

Based on the above embodiments, the present disclosure provides a semiconductor structure to improve problems resulted from RC delay of integrated circuits.

The foregoing description of the exemplary embodiments of the invention has been presented only for the purposes of illustration and description and is not intended to be exhaustive or to limit the invention to the precise forms disclosed. Many modifications and variations are possible in light of the above teaching.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A semiconductor structure, comprising:
a substrate, comprising:
a source region, located in a first area of the substrate; and
a drain region, located in a second area of the substrate; and
a gate structure, comprising:
a first gate region, disposed above the first area of the substrate or disposed above the second area of the substrate,
a second gate region, disposed above a third area of the substrate, wherein a second height of the second gate region is higher than a first height of the first gate region.

2. The semiconductor structure of claim 1, wherein the first area and the second area are located at two opposite sides of the substrate respectively.

3. The semiconductor structure of claim 1, wherein the source region further comprises a first lightly doped drain (LDD) region, wherein the drain region further comprises a second lightly doped drain (LDD) region.

4. The semiconductor structure of claim 1, wherein the first gate region comprises two first gate regions, wherein one of the two first gate regions is disposed above the first area of the substrate, and the other one of the two first gate regions is disposed above the second area of the substrate.

5. The semiconductor structure of claim 4, wherein the two first gate regions are coupled to the drain region and the source region respectively.

6. The semiconductor structure of claim 1, wherein the third area is between the first area and the second area, and the third area is in contact with the first area and the second area.

7. The semiconductor structure of claim 6, wherein the third area is located at a center of the substrate.

8. The semiconductor structure of claim 1, wherein a proportion of the first height of the first gate region to the second height of the second gate region is about 50%.

9. The semiconductor structure of claim 1, wherein a proportion of the first height of the first gate region and to second height of the second gate region is about 35%.

10. The semiconductor structure of claim 1, wherein a proportion of the first height of the first gate region and to second height of the second gate region is about 20%.
